(19) United States
(12) Patent Application Publication
(10) Pub. No.: US 2024/0381579 A1
(43) Pub. Date: Nov. 14, 2024

(54) Thermal Management and Control System

(71) Applicant: DZS Inc., Plano, TX (US)

(72) Inventors: Scott Agnew, Kanata (CA); Lloyd Schenher, Almonte (CA)

(21) Appl. No.: 18/657,453

(22) Filed: May 7, 2024

Related U.S. Application Data
(60) Provisional application No. 63/501,268, filed on May 10, 2023.

(51) Int. Cl. H05K 7/20

(52) U.S. Cl. CPC H05K 7/20436; H05K 7/20509; H05K 7/207

(57) ABSTRACT

According to one example, a method performed includes, with a control system, controlling a first thermoelectric component of a heating system in thermal connection with an enclosure defined by a housing, the first thermoelectric component being positioned external to the housing to provide heat to a device within the enclosure. With the control system, the method further includes controlling a second thermoelectric component of a cooling system in thermal connection with the enclosure, the second thermoelectric component being positioned within the housing to provide cooling to the device.

### CROSS-REFERENCE TO RELATED APPLICATIONS

The present application claims the benefit of U.S. Provisional Patent Application 63/501,268, which was filed on May 10, 2023, the disclosure of which is hereby incorporated by reference in its entirety.

### BACKGROUND

Various types of commercial communication equipment and other types of optical or electronic equipment are often placed in outdoor environments that are susceptible to extreme temperature variations. For example, equipment may be located in challenging environments where the communication equipment may be subjected to high and low temperatures falling outside the operating ranges of that equipment.

### SUMMARY

According to one example, a method performed includes, with a control system, controlling a first thermoelectric component of a heating system in thermal connection with an enclosure defined by a housing, the first thermoelectric component being positioned external to the housing to provide heat to a device within the enclosure. With the control system, the method further includes controlling a second thermoelectric component of a cooling system in thermal connection with the enclosure, the second thermoelectric component being positioned within the housing to provide cooling to the device.

### BRIEF DESCRIPTION OF THE DRAWINGS

Aspects of the present disclosure are best understood from the following detailed description when read with the accompanying figures.

FIG. 1 is a diagram showing an illustrative thermal management and control system for equipment placed within an enclosure, according to one example of principles described herein.

FIGS. 2A, 2B, and 2C are diagrams showing illustrative heat transfer plates, according to one example of principles described herein.

FIG. 3 is a flowchart showing an illustrative process for managing the temperature at a desired level within an enclosure, according to one example of principles described herein.

FIG. 4 is a flowchart showing an illustrative process for managing the temperature within a desired range within an enclosure, according to one example of principles described herein.

FIG. 5 is a diagram showing illustrative temperature range over time, according to one example of principles described herein.

FIG. 6 is a flowchart showing an illustrative process for managing the temperature within an enclosure according to a thermal prediction model, according to one example of principles described herein.

FIG. 7 is a flowchart showing an illustrative process for maintaining a thermal prediction model, according to one example of principles described herein.

FIG. 8 is a flowchart showing an illustrative process for managing the temperature within an enclosure based on measured parameters, according to one example of principles described herein.

FIG. 9 is a diagram showing an illustrative computing system that may be used to perform processes related to flow orchestration for network configuration, according to one example of principles described herein.

FIG. 10 is a flowchart showing an illustrative method for managing the temperature within an enclosure, according to principles described herein.

In the figures, elements having similar designations may or may not have the same or similar functions.

### DETAILED DESCRIPTION

In the following description, specific details are set forth describing some examples consistent with the present disclosure. It will be apparent, however, to one skilled in the art that some examples may be practiced without some or all of these specific details. The specific examples disclosed herein are meant to be illustrative but not limiting. One skilled in the art may realize other elements that, although not specifically described here, are within the scope and the spirit of this disclosure. In addition, to avoid unnecessary repetition, one or more features shown and described in association with one example may be incorporated into other examples unless specifically described otherwise or if the one or more features would make an example non-functional.

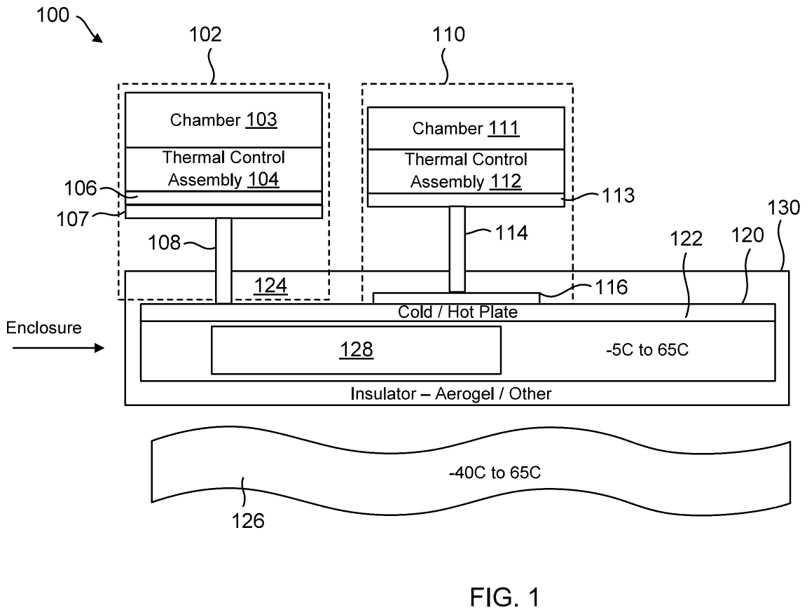

FIG. 1 is a diagram showing an illustrative thermal management and control system 100 for a piece of equipment 128 placed within a housing 130. The housing 130 forms an enclosure 122 in which the equipment is held. To keep the temperature inside the enclosure 122 at appropriate operating temperatures, the thermal management control system 100 includes a heating system 102 and a cooling system 110.

The equipment 128 may include one or more modules that are used for various types of communication systems such as cellular communications, wi-fi systems, optical communication networks, etc. Various other types of equipment may be placed within the enclosure 122 as well. Such equipment 128 may be electrical or optical. For purposes of discussion, the equipment 128 within the enclosure will also be referred to as a device or temperature sensitive device.

The enclosure 122 includes a transfer plate 120 and an insulator 124. The transfer plate 120 is a structure that is designed to provide thermal conductivity and transfer heat from one side to the other. The transfer plate 120 may have a physical profile of varying thickness according to thermal load and dissipation characteristics to normalize temperature on surfaces that contact a temperature sensitive device. The transfer plate 120 may have a design that allows dynamic coupling and uncoupling of an optical-electronic device of a standardized dimension and construction. This would allow the device to be removed and/or replaced from the system while in operation. The thermal plate may also be constructed of two (or more) phases of material providing a varied thermal conductivity in different regions.

The insulator 124 may include aerogel or other known types of insulator materials. The insulator may optionally have a hermetic seal to contain thermally conductive dielectric liquid. The insulator 124 may be fabricated using cast, additive, or substrative manufacturing techniques. The insulator 124 may include low k ceramic, polymer matrix, or multi-phase materials.

The heating system 102 includes a heat pipe 108 in thermal connection with the transfer plate 120. The heating system 102 may include its own heat transfer plate 107, a thermoelectric component 106, and a heating controller 104. The heating system 102 is configured to provide heat to the enclosure 122 during situations in which the external environment 126 exhibits relatively cold temperature such that without the heating system, the enclosure would fall below desired operating temperatures.

The heat pipe 108 is connected between the housing 130 and the transfer plate 107 of the heating system 102. Specifically, the heat pipe 108 provides thermal conduction between the thermal plate 120 of the housing 130 and the thermal plate 107 of the heating system 102. In the present example, the thermoelectric component 106 of the heating system 102 is positioned external to the housing 130.

The thermal plate 107 provides thermal conduction between the heat pipe 108 and the thermoelectric component 106 of the heating system 102. As such, the thermal plate 107 transfers heat from the thermoelectric component 106 to the heat pipe 108.

The thermoelectric component 106 is a plate that transfers heat from one side to the other using the Peltier effect. In other words, the thermoelectric component 106 provides heating or cooling in response to application of an electric current. The thermoelectric component 106 may be referred to as a thermoelectric cooler (TEC) or Peltier device.

The controller 104 for the heat system 102 is configured to control the thermoelectric component 106 and deliver heat to the enclosure 130 in response to certain conditions. For example, if the temperature within the enclosure falls to a certain point such that heating would be desired, the controller 104 can activate the thermoelectric component 106 and provide such heat.

The chamber 103 may be a skived chamber or a vapor chamber from which thermal energy can be drawn and delivered through the thermoelectric component 106 to the enclosure 122.

The cooling system 110 includes a heat pipe 114, a thermoelectric component (TEC) 116, its own thermal transfer plate 132, and a cooling controller 112. The cooling controller 112 is configured to provide cooling to the enclosure in situations where the external environment 126 is relatively hot or operation of the communication equipment 128 itself would raise the temperature within the enclosure 122 (or the temperature of the device 128) above desired operating temperatures.

The thermoelectric component 116 of the cooling system is placed within the housing 130. It is positioned so as to have thermal contact with the transfer plate 120 of the housing 130. Upon application of an electric current, the thermoelectric component 116 removes heat from within the enclosure 122 and exhausts it through the heat pipe 114.

The heat pipe 114 provides thermal conduction between the housing 130 and the thermal plate 113 that is placed external to the housing 130. The thermal plate 113 may then vent that heat into a skived or vapor chamber 111 of the cooling system 110.

The controller 112 for the cooling system 110 is configured to control the thermoelectric component 116 and transfer heat from the enclosure 130 in response to certain conditions. For example, if the temperature within the enclosure rises to a certain point such that cooling would be desired, the controller 112 can activate the thermoelectric component 116 and provide such cooling.

In some examples, the controller 112 for the cooling system and the controller for the heating system 114 may be integrated as a single control system. In some examples, both controllers 112 may communicate and work with a primary control system (not shown) that oversees both heating and cooling systems. The processing circuitry for the controllers may be placed either within the enclosure 122 or external to the enclosure 122.

By using separate heating and cooling systems that both use a thermoelectric component, the different systems can be designed to maximize efficiency for their respective purposes. For example, the thermoelectric component 106 of the heating system 102 can be placed external to the device to better provide heating to the enclosure 122. Additionally, the thermoelectric component 116 of the cooling system 110 can be placed within the enclosure to better provide cooling to the enclosure.

While the present example illustrates a single heating system 102 and a single cooling system 110, it will be understood that a particular housing 130 may include multiple heating systems or multiple cooling systems positioned at strategic points of the housing. For example, heating and cooling systems may be placed at positions of the housing that will provide more direct heating and cooling to particular devices or sections of devices within the enclosure 130.

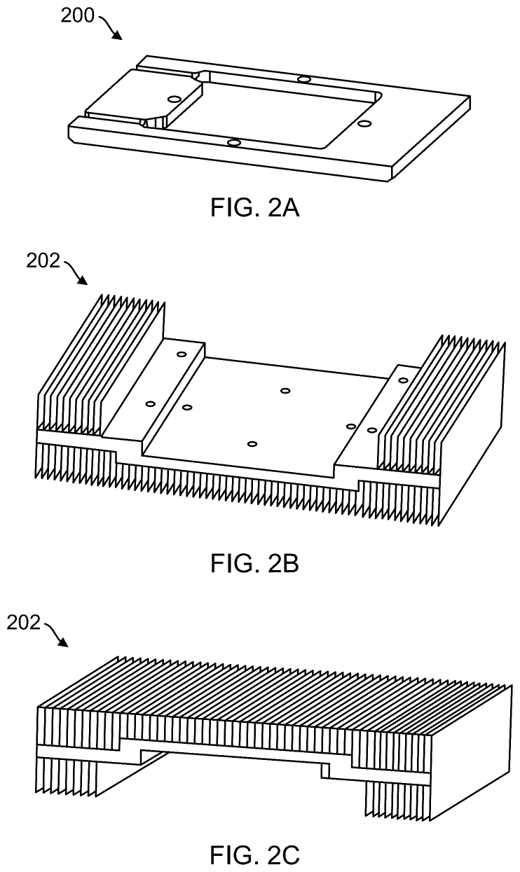

FIGS. 2A, 2B, and 2C are diagrams showing illustrative heat transfer plates, according to one example of principles described herein. FIG. 2A illustrates an example of thermoelectric component plate housing 200 for the thermoelectric component 106 or 116. The thermoelectric component plate housing ensures uniform thermal distribution and maximizes surface area transfer from one side of the thermoelectric component to the other. The thermoelectric component housing 200 may also be designed to prevent thermal loops. FIGS. 2B and 2C illustrate top and bottom views of a thermal spreader. The thermal spreader 202 may be used as part of any of the transfer plates described above.

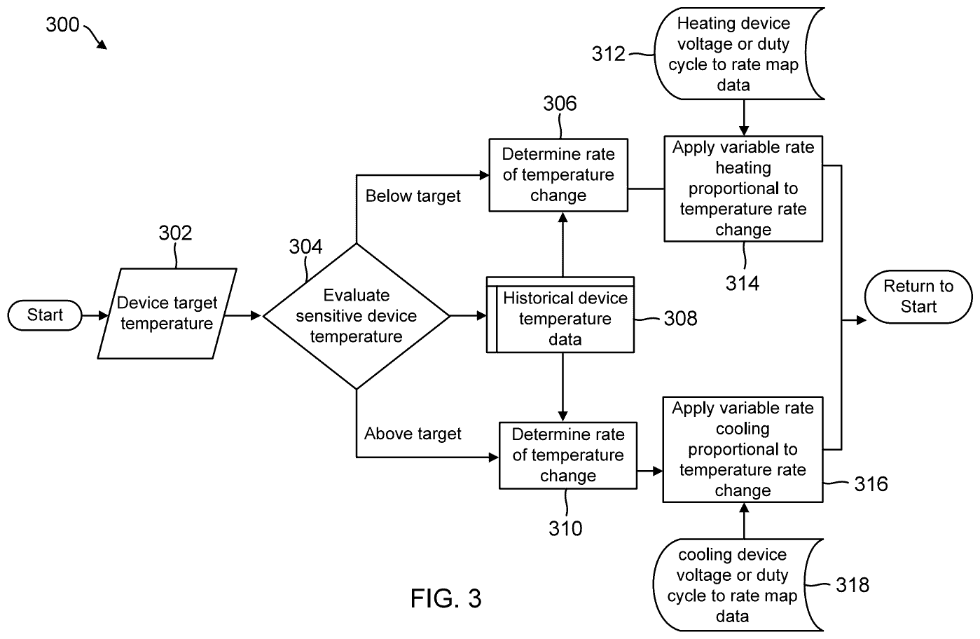

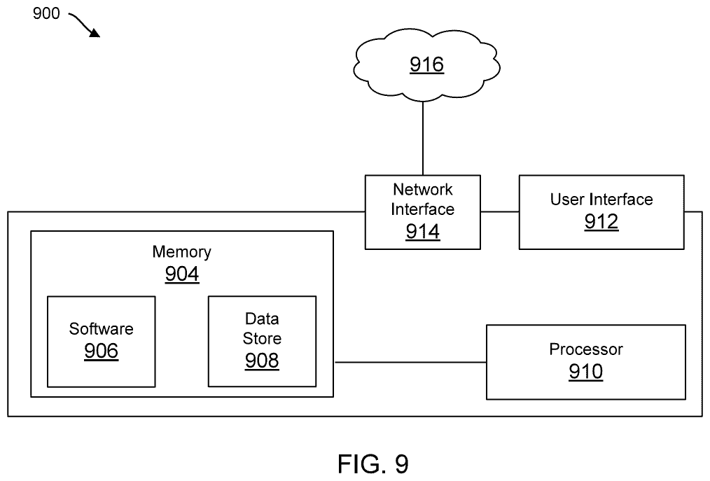

FIG. 3 is a flowchart showing an illustrative process for managing the temperature at a desired level within an enclosure. The process may be performed by a control system (e.g., as described below with respect to FIG. 9) that controls the heating and cooling systems described above with respect to FIGS. 1 and 2. According to the present example, the method 300 starts at process 302, in which a control system determines a target temperature for a particular piece of communication equipment within the enclosure. At process 304, it is determined whether the current temperature of that communication equipment is above or below the target temperature. This can be done using various tools such as a thermometer associated with the communication equipment. If the current temperature of the communication equipment is below the target temperature, then the method 300 proceeds to process 306.

At process 306, the control system determines the current rate of temperature change. This can be done by analyzing historical data 308 as to the past temperatures of the communication device.

At process 314, the control system applies heating that is proportional to the rate of temperature change. For example, if temperature is decreasing relatively rapidly, then a higher level of heating may be applied (e.g., by applying more current to the thermoelectric component). If, however, temperature is decreasing slowly, then a lesser degree of heating may be applied (e.g., by applying a smaller amount of current to the thermoelectric component). The control system may use heating rate map data 312 to determine how to apply the desired amount of heating. For example, the heating rate map data 312 may instruct the control system as to how much voltage/current should be applied to the thermoelectric component. The heating rate map data 312 may also define specific frequencies and/or duty cycles of the signal that drives the thermoelectric component.

If, at process 304, it is determined that the current temperature of the communication equipment is above the target temperature, then the method 300 proceeds to process 310.

At process 310, the control system determines the current rate of temperature change. This can be done by analyzing historical data 308 as to the past temperatures of the communication device.

At process 316, the control system applies cooling that is proportional to the rate of temperature change. For example, if temperature is increasing relatively rapidly, then a higher level of cooling may be applied (e.g., by applying more current to the thermoelectric component). If, however, temperature is increasing slowly (or even slightly decreasing), then a lesser degree of cooling may be applied (e.g., by applying a smaller amount of current to the thermoelectric component). The control system may use cooling rate map data 318 to determine how to apply the desired amount of cooling. For example, the cooling rate map data 318 may instruct the control system as to how much voltage/current should be applied to the thermoelectric component. The cooling rate map data 318 may also define specific frequencies and/or duty cycles of the signal that drives the thermoelectric component.

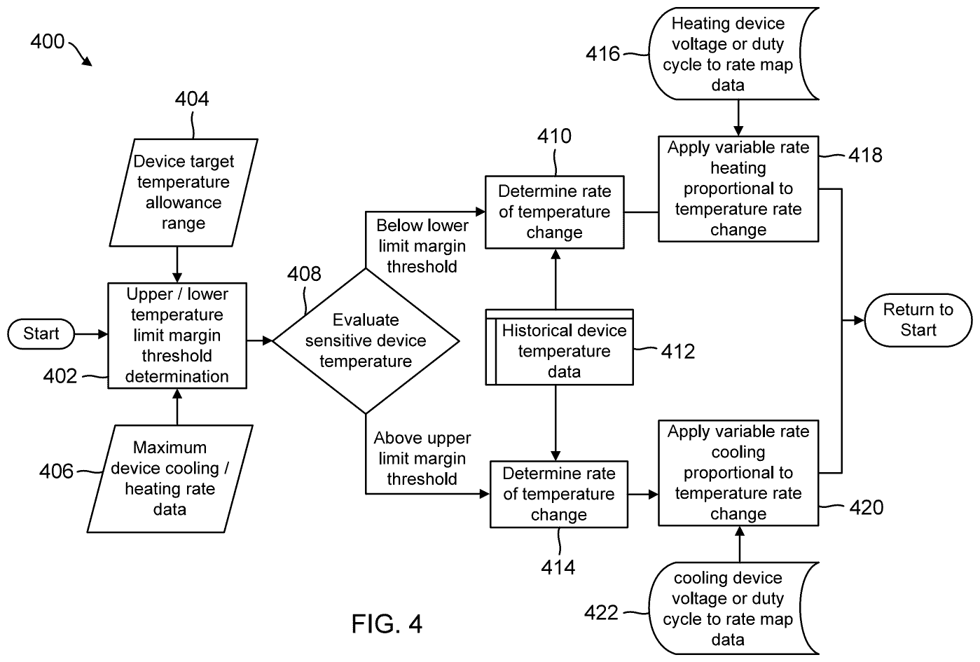

FIG. 4 is a flowchart showing an illustrative process for managing the temperature within a desired range within an enclosure. The process may be performed by a control system (e.g., as described below with respect to FIG. 9) that controls the heating and cooling systems described above with respect to FIGS. 1 and 2. According to the present example, the method 300 starts at process 402, at which a control system determines a target temperature range for a particular piece of communication equipment within the enclosure. This temperature range includes an upper temperature limit and a lower temperature limit. The range may be defined by temperature allowance data 404 associated with the communication equipment. The system may also consider the maximum heating and cooling rates 406 for particular equipment. For example, some pieces of communication equipment may be overstressed if exposed to higher changes in temperature.

At process 408, it is determined whether the current temperature of the communication equipment is above the upper limit or below the lower limit. This can be done using various tools such as a thermometer associated with the communication equipment. If the current temperature of the communication equipment is below the lower limit, then the method 400 proceeds to process 410.

At process 410, the control system determines the current rate of temperature change. This can be done by analyzing historical data 412 as to the past temperatures of the communication device.

At process 418, the control system applies heating that is proportional to the rate of temperature change. For example, if temperature is decreasing relatively rapidly, then a higher level of heating may be applied (e.g., by applying more current to the thermoelectric component). If, however, temperature is decreasing slowly, then a lesser degree of heating may be applied (e.g., by applying a smaller amount of current to the thermoelectric component). The control system may use heating rate map data 416 to determine how to apply the desired amount of heating. For example, the heating rate map data 416 may instruct the control system as to how much voltage/current should be applied to the thermoelectric component. The heating rate map data 416 may also define specific frequencies and/or duty cycles of the signal that drives the thermoelectric component.

If, at process 408, it is determined that the current temperature of the communication equipment is above the upper temperature limit, then the method 400 proceeds to process 414.

At process 414, the control system determines the current rate of temperature change. This can be done by analyzing historical data 412 as to the past temperatures of the communication device.

At process 420, the control system applies cooling that is proportional to the rate of temperature change. For example, if temperature is increasing relatively rapidly, then a higher level of cooling may be applied (e.g., by applying more current to the thermoelectric component). If, however, temperature is increasing slowly (or even slightly decreasing), then a lesser degree of cooling may be applied (e.g., by applying a smaller amount of current to the thermoelectric component). The control system may use cooling rate map data 422 to determine how to apply the desired amount of cooling. For example, the cooling rate map data 422 may instruct the control system as to how much voltage/current should be applied to the thermoelectric component. The cooling rate map data 422 may also define specific frequencies and/or duty cycles of the signal that drives the thermoelectric component.

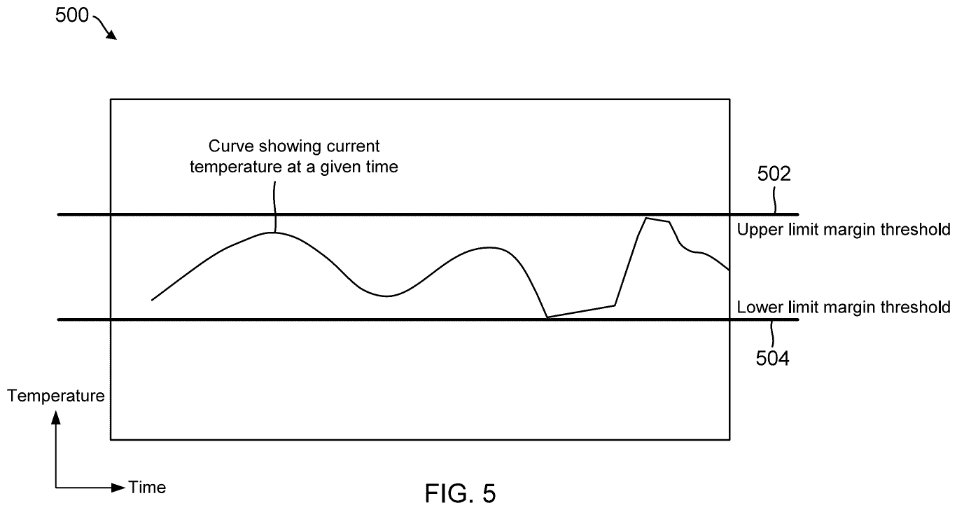

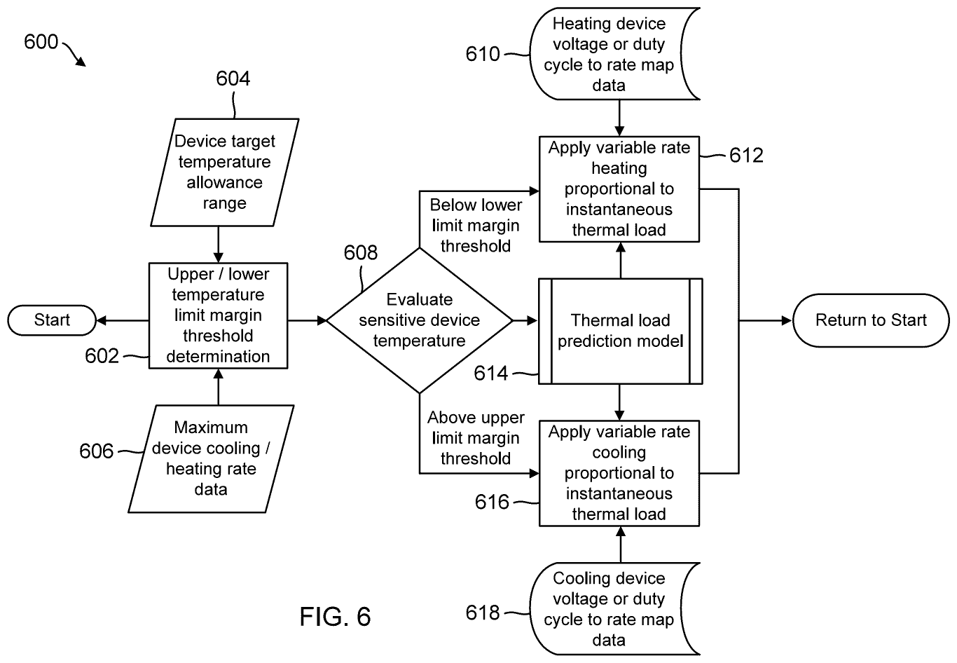

FIG. 5 is a diagram showing an illustrative temperature range 500. The temperature range includes an upper temperature limit 502 as described above and below with respect to FIGS. 4 and 6. The temperature range further includes a lower temperature limit 504 as described above and below with respect to FIGS. 4 and 6.

FIG. 6 is a flowchart showing an illustrative process for managing the temperature within an enclosure according to a thermal prediction model. The process may be performed by a control system (e.g., as described below with respect to FIG. 9) that controls the heating and cooling systems described above with respect to FIGS. 1 and 2. The method 600 in FIG. 6 is similar to that of FIG. 4. Rather than using historical data to determine the temperature range, the control system relies on a thermal load prediction model. According to the present example, the method 600 starts at process 602, at which a control system determines a target temperature range for a particular piece of communication equipment within the enclosure. The range may be defined by temperature allowance data 604 associated with the communication equipment. The system may also consider the maximum heating and cooling rates 606 for particular equipment.

At process 608, it is determined whether the current temperature of the communication equipment is above the upper limit or below the lower limit. If the current temperature of the communication equipment is below the lower limit, then the method 600 proceeds to process 612.

At process 612, the control system uses a thermal load prediction model to predict how application of a certain amount of heating (as defined by heating data 610) will affect the current temperature under the current thermal load. The thermal load may be defined in watts. The thermal load represents the amount of heat dissipation of the device. The control system then applies heating in accordance with the thermal load prediction model 614.

If, at process 608, it is determined that the current temperature of the communication equipment is above the upper temperature limit, then the method 600 proceeds to process 616. At process 616, the control system uses a thermal load prediction model to predict how application of a certain amount of cooling (as defined by cooling data 618) will affect the current temperature under the current thermal load. The control system then applies cooling in accordance with the thermal load prediction model.

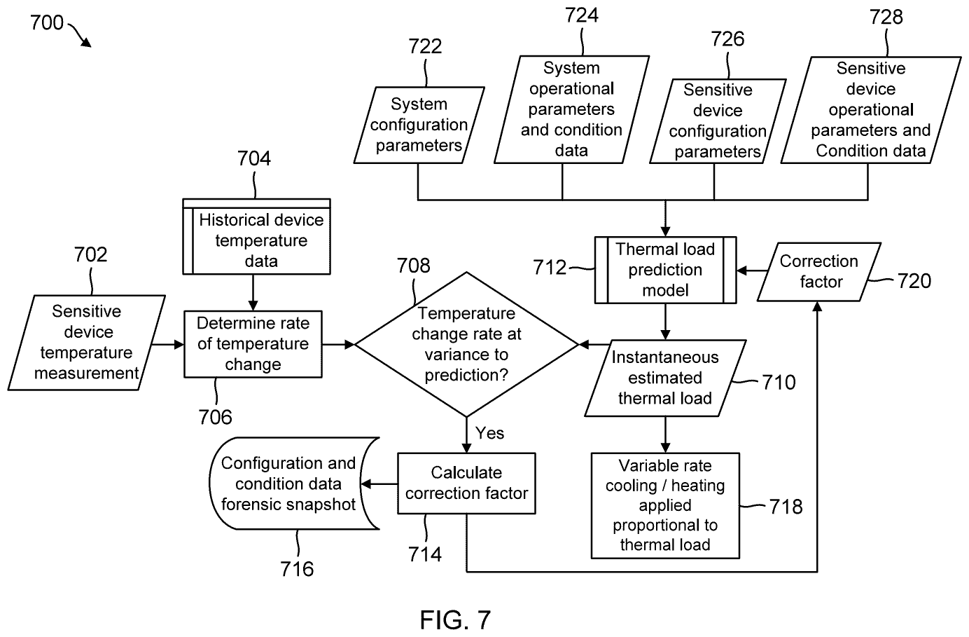

FIG. 7 is a flowchart showing an illustrative process for maintaining a thermal prediction model. The process may be performed by a control system (e.g., as described below with respect to FIG. 9) that controls the heating and cooling systems described above with respect to FIGS. 1 and 2. According to the present example, the method 700 starts at process 702, at which a control system measures the current temperature of a piece of communication equipment. At process 706, the control system determines the current rate of temperature change. This is done using historical temperature data 704.

At process 708 it is determined whether the current temperature change rate is different than what the thermal load model predicts. If so, then the control system calculates a correction factor at process 714. As part of this calculation process, the control system takes a snapshot 716 of various configurations and conditions of both the heating/cooling systems and the communication equipment itself. The correction factor 720 is then used to update the thermal load prediction model 712.

The thermal load prediction model 712 may rely on various pieces of information. The thermal load prediction model may also take into account the communication equipment configuration parameters 726. For example, the equipment may be configured to transmit data with a laser tuned at various frequencies. The equipment may also be configured to transmit data at different data rates. These configuration parameters may affect the device's tendency to increase in temperature, as well as the desired operating temperature of the device.

The thermal load prediction model may also take into account the communication equipment conditional parameters 728. This may include various telemetry parameters detected by the device. This may include electrical current consumption of the device, what amount of optical power is being received or transmitted.

For example, the prediction model 712 may take into account the system configuration parameters 722. System parameters include configuration of multiple devices within a communication system. For example, if the device 128 is a piece of networking equipment, then the status of other devices (either within the same enclosure or elsewhere) may also have an affect on the thermal load of the temperature sensitive device. The thermal load prediction model may also take into account the system conditional parameters 724.

Using these parameters 722, 724, 726, 728 and the correction factor 720, the control system may use the prediction model to produce an estimated instantaneous thermal load 710. That estimated thermal load is used for comparison in process 708, described earlier.

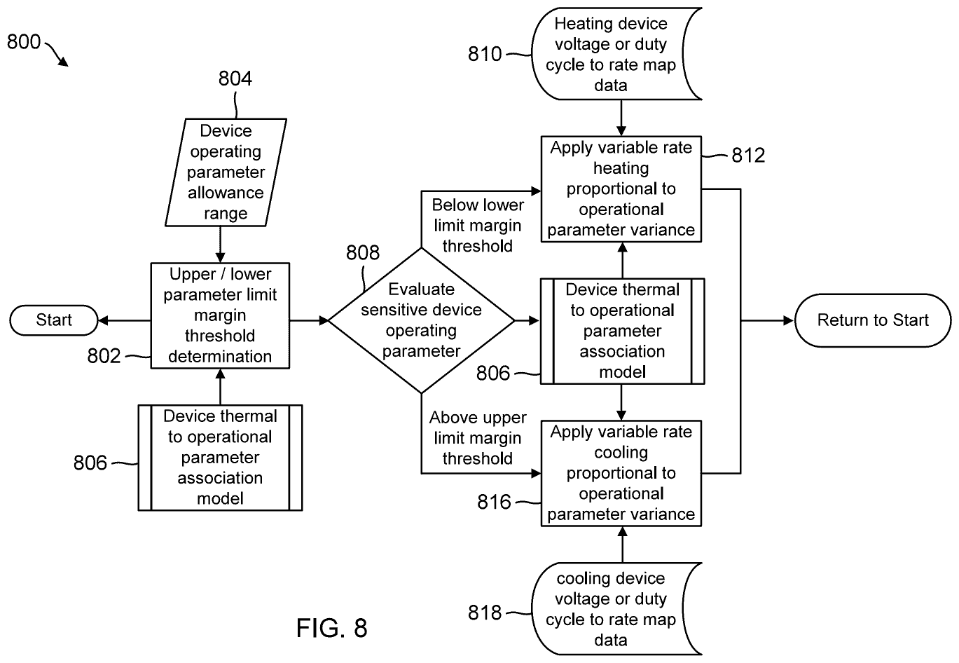

FIG. 8 is a flowchart showing an illustrative process for managing the temperature within an enclosure based on measured parameters. The process may be performed by a control system (e.g., as described below with respect to FIG. 9) that controls the heating and cooling systems described above with respect to FIGS. 1 and 2. The method 800 in FIG. 8 is similar to that of FIG. 6 but measures certain parameters of the communication device. These parameters may include temperature, thermal demand, operating parameters, or operating history.

According to the present example, the method 800 starts at process 802, at which a control system determines a target parameter range for a particular piece of communication equipment within the enclosure. The range may be defined by parameter allowance data 804 associated with the communication equipment. If the parameter is something other than temperature, then the control system may use an association model 806 to associate the measured parameter with temperature. For example, if the measured parameter is computational load of the device, then the model may associate computational load with temperature.

At process 808, it is determined whether the current parameter measurement of the communication equipment is above the upper limit or below the lower limit. If the parameter measurement of the communication equipment is below the lower limit, then the method 800 proceeds to process 812.

At process 812, the control system applies heating in accordance with the association model 806. The control system further uses heating rate map data 810 to determine how to control the heating system to apply the desired amount of heating. If, at process 808, it is determined that the current measured parameter of the communication equipment is above the upper temperature limit, then the method 800 proceeds to process 816. At process 816, the control system uses association model to predict how application of a certain amount of cooling (as defined by cooling data 818) will affect the current measured parameter. The control system then applies cooling in accordance with the association model.

FIG. 9 is a diagram showing an illustrative computing system that may be used to perform thermal control and management. The computing system 900 may represent the heating system 102, cooling system 110, controllers 104 and/or 112, control system, or any other computing system that performs functions described above with respect to FIG. 1. The control system may also perform the methods described in FIGS. 3, 4, 6, 7, and 8. In some examples, the computing system 900 may be implemented as a specially made machine that is specially programed to perform functions relating to thermal management of communication equipment.

The computing system 900 may include a bus (or other communication mechanism) which interconnects subsystems and components for transferring information within the computing system 900. As shown, the computing system 900 includes one or more processors 910, user interface 912, which may include input/output (“I/O”) devices, network interface 914 (e.g., a modem, Ethernet card, or any other interface configured to exchange data with a network), and one or more memories 904 storing pieces of software 906 including, for example, server app(s) and an operating system. The memory may further include a data store, and can communicate with an external database (which, for some examples, may be included within the computing system 900).

The processor 910 may be one or more processing devices configured to perform functions of the disclosed methods, such as a microprocessor manufactured by Intel™ or manufactured by AMD™. The processor 910 may comprise a single core or multiple core processors executing parallel processes simultaneously. For example, the processor 910 may be a single core processor configured with virtual processing technologies. In certain examples, the processor 910 may use logical processors to simultaneously execute and control multiple processes. The processor 910 may implement virtual machine technologies, or other technologies to provide the ability to execute, control, run, manipulate, store, etc. multiple software processes, applications, programs, etc. In some examples, the processor 910 may include a multiple-core processor arrangement (e.g., dual, quad core, etc.) configured to provide parallel processing functionalities to allow the computing system 900 to execute multiple processes simultaneously. It is appreciated that other types of processor arrangements could be implemented that provide for the capabilities disclosed herein.

The memory 904 may be a volatile or non-volatile, magnetic, semiconductor, tape, optical, removable, non-removable, or other type of storage device or tangible or non-transitory computer-readable medium that stores one or more program(s) such as server apps and an operating system. Common forms of non-transitory media include, for example, a flash drive a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same.

The computing system 900 may include one or more storage devices configured to store information used by processor 910 (or other components) to perform certain functions related to the disclosed examples. For example, the computing system 900 may include memory 904 that includes instructions to enable the processor 910 to execute one or more applications, such as software 906, and any other type of application or software known to be available on computer systems. Alternatively or additionally, the instructions, application programs, etc. may be stored in an external database (which can also be internal to the computing system 900) or external storage communicatively coupled with the computing system 900 (not shown), such as one or more database or memory accessible over the network 908.

The database or other external storage may be a volatile or non-volatile, magnetic, semiconductor, tape, optical, removable, non-removable, or other type of storage device or tangible or non-transitory computer-readable medium. The memory 904 and database may include one or more memory devices that store data and instructions used to perform one or more features of the disclosed examples. The memory 904 and database may also include any combination of one or more databases controlled by memory controller devices (e.g., server(s), etc.) or software, such as document management systems, Microsoft™ SQL databases, SharePoint databases, Oracle™ databases, Sybase™ databases, or other relational databases.

In some examples, the operating system may perform operating system functions when executed by one or more processors such as the processor 810. By way of example, the operating system may include Microsoft Windows™, Unix™, Linux™ Apple™ operating systems, Personal Digital Assistant (PDA) type operating systems, such as Apple iOS™, Google Android™, Blackberry OS™, or other types of operating systems. Accordingly, disclosed examples may operate and function with computer systems running any type of operating system. The computing system 800 may also include software that, when executed by a processor, provides communications with network 916 through the network interface 914 and/or a direct connection to one or more network devices.

In some examples, the data 908 may include, for example, network configurations, system parameters, system conditional data, device parameters, device conditional data, association models, or any other form of data described herein.

The computing system 900 may also include one or more I/O devices having one or more interfaces for receiving signals or input from devices and providing signals or output to one or more devices that allow data to be received and/or transmitted by the computing system 900. For example, the computing system 900 may include interface components for interfacing with one or more input devices, such as one or more keyboards, mouse devices, and the like, that enable the computing system 900 to receive input from an operator or administrator (not shown).

Some examples of processing systems described herein may include non-transitory, tangible, machine readable media that include executable code that when run by one or more processors may cause the one or more processors to perform the processes of methods as described above. Some common forms of machine readable media that may include the processes of methods are, for example, floppy disk, flexible disk, hard disk, magnetic tape, any other magnetic medium, CD-ROM, any other optical medium, RAM, PROM, EPROM, FLASH-EPROM, any other memory chip or cartridge, and/or any other medium from which a processor or computer is adapted to read.

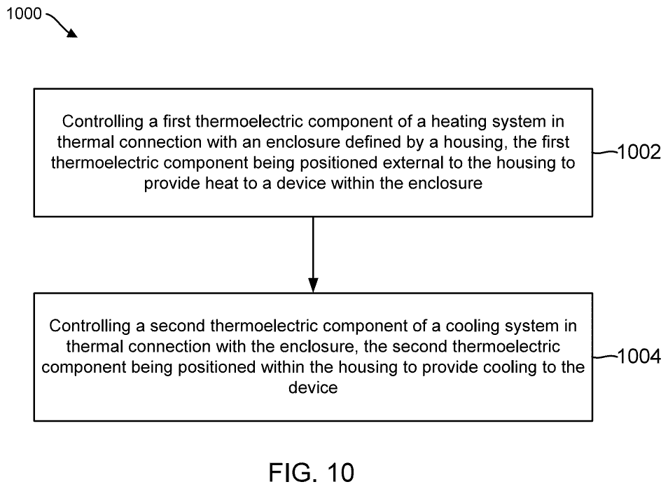

FIG. 10 is a flowchart showing an illustrative method for managing the temperature within an enclosure, according to principles described herein. According to one example, a method 1000 includes, with a control system, controlling 1002 a first thermoelectric component of a heating system in thermal connection with an enclosure defined by a housing, the first thermoelectric component being positioned external to the housing to provide heat to a device within the enclosure. With the control system, the method further includes controlling 1004 a second thermoelectric component of a cooling system in thermal connection with the enclosure, the second thermoelectric component being positioned within the housing to provide cooling to the device.

Although illustrative examples have been shown and described, a wide range of modification, change and substitution is contemplated in the foregoing disclosure and in some instances, some features of the examples may be employed without a corresponding use of other features. One of ordinary skill in the art would recognize many variations, alternatives, and modifications. Thus, the scope of the disclosure should be limited only by the following claims, and it is appropriate that the claims be construed broadly and in a manner consistent with the scope of the examples disclosed herein.

What is claimed is:

1. A method comprising:
with a control system, controlling a first thermoelectric component of a heating system in thermal connection with an enclosure defined by a housing, the first thermoelectric component being positioned external to the housing to provide heat to a device within the enclosure; and
with the control system, controlling a second thermoelectric component of a cooling system in thermal connection with the enclosure, the second thermoelectric component being positioned within the housing to provide cooling to the device.

2. The method of claim 1, further comprising, with the control system, applying both heating and cooling to maintain the device at a target temperature.

3. The method of claim 1, further comprising, with the control system, applying both heating and cooling to maintain the device within a desired temperature range.

4. The method of claim 1, further comprising, applying heating and cooling at varying rates to keep the temperature of the device within a desired temperature range.

5. The method of claim 1, further comprising, maintaining a model defining an estimated thermal load of the device.

6. The method of claim 5, further comprising, applying heating and cooling to the device based on the model.

7. The method of claim 5, wherein the model takes into account configurations and operating conditions of the device.

8. The method of claim 5, wherein the model takes into account configurations and operating conditions of a communication system of which the device is a part.

9. The method of claim 1, further comprising, with the control system, applying both heating and cooling to maintain the device within a desired temperature range based on input of a measured parameter from the device, wherein the measured parameter includes at least one of a computational load of the device, an operating frequency of the device, and a wavelength of a laser associated with the device.

10. A system comprising:
a housing defining an enclosure, the housing comprising a first thermal transfer plate;
a heating system comprising a first thermoelectric component that is positioned exterior to the housing and in thermal connection with the first thermal transfer plate;
a cooling system comprising a second thermoelectric component that is positioned within the housing and in thermal connection with the first thermal transfer plate; and
a control system configured to:
activate the first thermoelectric component to apply heating to a device within the enclosure; and
activate the second thermoelectric component to apply cooling to the device.

11. The system of claim 10, wherein the heating system further includes a second thermal transfer plate external to the housing.

12. The system of claim 11, further comprising a first heat pipe connecting the first thermal transfer plate and the second thermal transfer plate.

13. The system of claim 12, wherein the second thermal transfer plate is positioned between the first heat pipe and the first thermoelectric component.

14. The system of claim 12, wherein the first thermoelectric component is positioned between the second thermal transfer plate and a first chamber.

15. The system of claim 11, wherein the cooling system further includes a third thermal transfer plate placed external to the housing.

16. The system of claim 15, wherein the cooling system comprises a second heat pipe positioned between the second thermoelectric component and the third thermal transfer plate.

17. The system of claim 16, wherein the third thermal transfer plate is positioned between the second heat pipe and a second chamber.

18. The system of claim 10, wherein the housing is surrounded by an insulator material.

19. A system comprising:
a processor; and
a memory comprising machine readable instructions that when executed by the processor cause the system to:
control a first thermoelectric component of a heating system in thermal connection with an enclosure defined by a housing, the first thermoelectric component being positioned external to the housing to provide heat to a device within the enclosure;
control a second thermoelectric component of a cooling system in thermal connection with the enclosure, the second thermoelectric component being positioned within the housing to provide cooling to the device.

20. The system of claim 19, wherein the system is further to apply both heating and cooling to maintain the device within a desired temperature range.
